(19) United States
(12) Patent Application Publication
(10) Pub. No.: US 2005/0266632 A1
(43) Pub. Date: Dec. 1, 2005

(54) Integrated circuit with strained and non-strained transistors, and method of forming thereof

(76) Inventors: Yun-Hsiu Chen, Hsin Chu City (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/991,840

(22) Filed: Nov. 18, 2004

Related U.S. Application Data
(60) Provisional application No. 60/574,483, filed on May 26, 2004.

(51) Int. Cl. H01L 21/8238

(52) U.S. Cl. 438/233

(57) ABSTRACT

Preferred embodiments of the present invention utilize system-level band gap engineering. Device improving structures, such as the strained source/drain regions for PMOS devices and a tensile film for NMOS devices, may be employed only in those selected regions such as where high drive current is necessary or desirable. In other regions of the integrated circuit, where high drive current is not a concern, conventional structures may be employed. In preferred embodiments, SiGe is employed for increasing the carrier mobility for PMOS devices. Preferably, the SiGe layer is located at source/drain regions, junction, or inside the channel region. Likewise, a tensile stress imposing film, preferably a silicon nitride film and more preferably a silicon nitride contact etch stop layer deposited using a plasma deposition technique, may be employed in those NMOS devices and device regions wherein enhanced electron mobility is necessary or desired.

This application claims the benefit of U.S. Provisional Application No. 60/574,483, filed on May 26, 2004, entitled Introduction of System-On-Chip (SOC) with Strained Silicon CMOS Transistor, which application is hereby incorporated herein by reference.

### CROSS-REFERENCE TO RELATED APPLICATIONS

This application relates to co-pending and commonly assigned patent application Ser. No. 10/423,513 (TSM03-0173), filed Apr. 25, 2003, entitled “Strained Channel Transistor and Methods of Manufacture;” and Ser. No. 10/786,643 (TSM03-0698) filed Feb. 25, 2004, entitled “CMOS Structure and Related Method.” Both applications are hereby incorporated herein by reference.

### TECHNICAL FIELD

This invention relates generally to semiconductor fabrication and more particularly to strained field effect transistors and methods of manufacture.

### BACKGROUND

For the upcoming network proliferation era, high performance broadband devices and circuits will be necessary to meet the emerging applications. System-on-chip (SOC) solutions, offering high performance transistors and embedded high density memories, are necessary to implement the high performance broadband devices, which help to scale up bandwidth and achieve desired high speeds and operating frequencies.

A system-on-chip (SOC) may include memory cell (e.g., DRAM, SRAM, Flash, EEPROM, EPROM), logic, analog and I/O devices. Logic circuits and some I/O devices usually need high performance transistors to achieve faster signal transitions. PMOS logic devices and certain I/O devices that require high drive current may be manufactured using selectively epitaxially grown strained material (e.g., SiGe) in the source and drain regions. Likewise for certain NMOS transistors of the SOC, enhanced electron mobility is desired. Enhanced electron mobility may be obtained by, e.g., a tensile film (e.g., Si₃N₄), which film may be deposited with an inherent tensile stress. This tensile stress will be transferred to the underlying channel for promoting electron mobility.

For other devices on the chip, however, speed performance is not as crucial. NMOS logic circuit devices, PMOS memory cell devices and other PMOS I/O devices or analog devices that do not require high drive current may be manufactured without the strain material or strain methodologies. These devices would not suffer from the concerns of manufacturing complexity, cost, and yield loss that affect the high drive current devices that do employ strained material in the source and drain area.

### SUMMARY OF THE INVENTION

These and other problems are generally solved or circumvented, and technical advantages are generally achieved, by preferred embodiments of the present invention that utilize system-level engineering in the manufacture of a SOC. Device improving structures, such as the strained material source/drain regions for PMOS devices and tensile film for the NMOS devices, may be employed only in selected regions such as where high drive current is necessary or desirable. In other regions of the integrated circuit, where high drive current is not a concern, conventional structures may be employed.

In preferred embodiments, SiGe is employed for increasing the carrier mobility for PMOS devices. Preferably, the SiGe layer is located at both the source/drain regions and at the junction or inside the channel region in order to significantly improve the performance of the PMOS devices.

In preferred embodiments, for NMOS transistors, current performance may be enhanced by, e.g., depositing under a tensile stress, a silicon nitride contact etch stop layer (CESL). The stress of the silicon nitride CESL is transferred to the underlying NMOS channel, and hence enhances the electron mobility. Preferably a silicon nitride film and more preferably a silicon nitride contact etch stop layer deposited using a plasma deposition technique, is employed in those NMOS devices and device regions wherein enhanced electron mobility is necessary or desired. Conventional NMOS structures may be employed elsewhere on the integrated circuit.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a plan view of a preferred system on a chip, SOC, architecture;

FIG. 2a shows a cross sectional view of a preferred embodiment comprising a strained silicon transistor with a relaxed SiGe layer as a stressor to induce strain in the top epitaxial strained silicon layer;

FIGS. 2b and 2c are cross sectional crystal lattice diagrams illustrating the origin of strain in a preferred Si/SiGe heterostructure;

FIG. 3 is a cross sectional view of another preferred method of introducing strain in a transistor channel using a high stress film as a stressor; and

FIG. 4 is a cross sectional view of an integrated circuit device made in accordance with preferred embodiments of the present invention.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

The present invention will be described with respect to preferred embodiments in a specific context, namely an integrated circuit device employing different stressors at different regions of the integrated circuit device. The stressors may include strain materials and strain inducing methodologies. The invention may also be applied, however, in other system on a chip, SOC, applications.

Several advantageous features are provided by preferred embodiments of the present invention. These include: manufacturing defect rates may be decreased, and hence yield increased, by using the strained material (e.g., SiGe) PMOS structures only in those regions of the integrated circuit (e.g., a system-on-chip device), wherein high performance (e.g., enhanced hole mobility, speed, drive current) is necessary or desired. By using more conventional structures in the remainder of the integrated circuit, defect density may be reduced.

PMOS performance and short channel effects will be impacted by the strained material deposition temperature and parameters. Consequently, another advantage of a preferred embodiment of the present invention is that device and process tuning becomes simplified if only those transistors that require the higher device performance need to be considered when optimizing the process parameters. The effects on other, non-high performance transistors (which will not include the strained material) may thus be ignored. For this same reason, the yield learning time will be shorter as a result of fewer devices and regions employing the more complex structures. Manufacturing cost will be cut as well.

Likewise, additional advantages of preferred embodiments of the present invention are in the performance of NMOS devices. More particularly, selected NMOS devices may be improved by adopting a tensile film. The above described advantages of tuning, yield improvement, and flexibility are obtained by selectively employing the tensile film in certain areas and/or by adopting the tensile film in combination with the above-described enhancements to PMOS devices. The contact etch process window and salicide loss at the gate, source and drain may also be improved through adoption of the strain inducing layer.

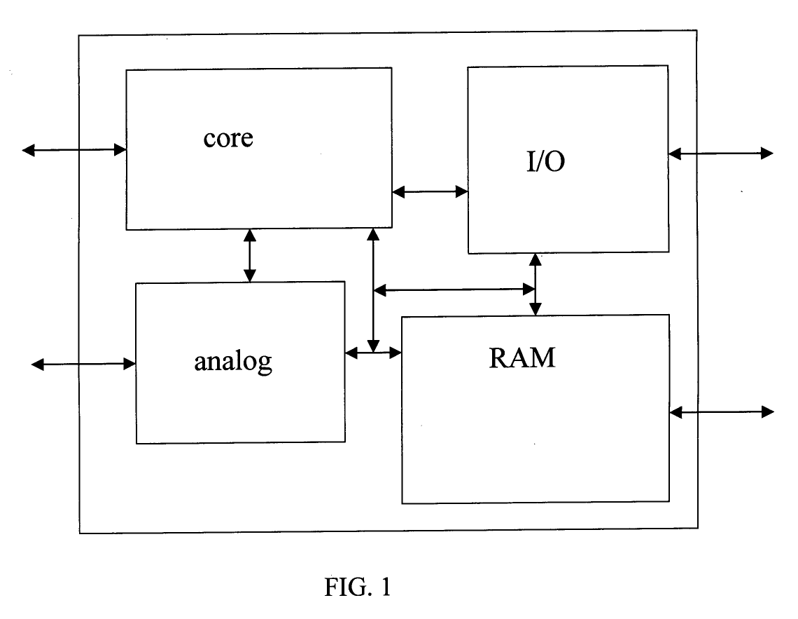

FIG. 1 illustrates a preferred embodiment of SOC architecture. For example, the SOC may comprise a core area wherein enhanced device performance is advantageous. The core area may employ performance enhancing materials and methodologies. In non-core areas wherein device performance is secondary to other manufacturing considerations, traditional manufacturing methods may be used. Non-core areas may include analog devices or I/O devices as illustrated in FIG. 1. The arrows in FIG. 1 represent communications means. One skilled in the art recognizes that analog devices or I/O devices may be included in the core area while other devices may comprise the non-core area. I/O devices may further comprise a data bus needing high current, a clock, a control signal, or other devices, or conventional transistors.

Shifting focus from the chip-level to the individual device level, it should be appreciated that shallow and abrupt source-drain (S/D) extension junction performance is an important challenge for scaling MOS transistor technology beyond the 100 nm technology node. However, it is necessary to overcome the short channel effect (SCE) for reduction of the device dimensions and for keeping the drive current sufficiently large. The short channel effect is especially significant for PMOS devices due to the source and drain junction being deeper than for typical NMOS devices.

Preferably, SiGe on non-recessed source/drain regions, such as raised source/drain regions, are used for shallow junction to suppress short channel effects. Moreover, it is known that silicon under a biaxial strain film, such as SiGe, may enhance carrier mobility, thus improving current performance. In another known structure, a PMOS transistor features an epitaxially grown SiGe film embedded in the source and drain region. Such a structure may be manufactured by etching the substrate to form recesses and selective epitaxial SiGe deposition in the recesses. The current performance of a PMOS device employing this structure will depend on the Ge composition, SiGe thickness, recess depth, and etching profile, among other factors.

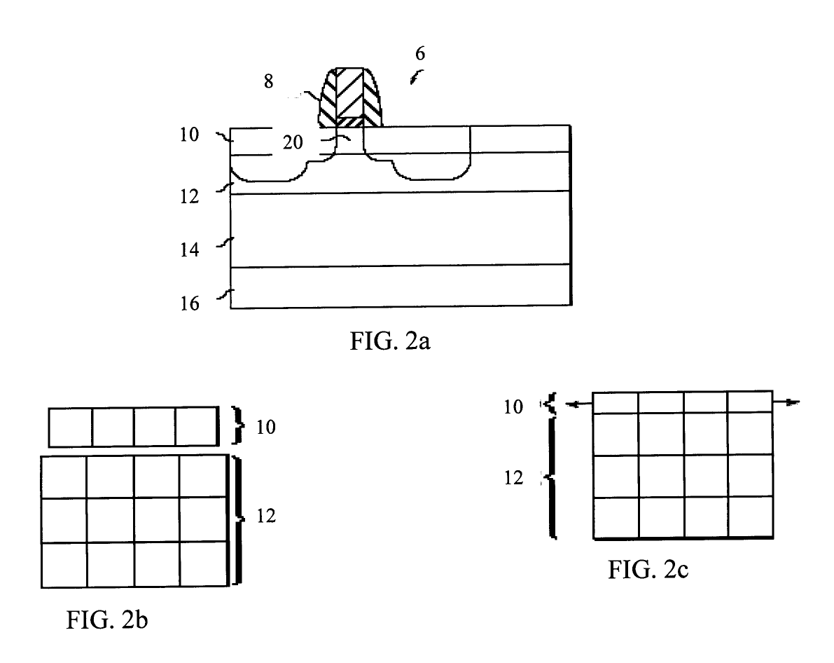

There are several approaches of introducing strain in the transistor channel region. In one preferred approach, described in a paper by J. Welser et al., published at the December 1992 International Electron Devices Meeting held in San Francisco, Calif., pp. 1000-1002 and incorporated herein by reference, a relaxed silicon germanium (SiGe) buffer layer is provided beneath the channel region. FIG. 2a shows such an approach.

Referring to FIG. 2a, a semiconductor device 6 includes a strained silicon layer 10 formed over and abutting a relaxed SiGe layer 12, which is formed over and abutting a graded SiGe buffer layer 14. The graded SiGe buffer layer 14 is formed over and abutting a silicon substrate 16.

The relaxed SiGe layer 12 has a larger lattice constant compared to relaxed Si, and the thin layer of strained silicon 10 grown on the relaxed SiGe 12 will have its lattice stretched in the lateral direction, i.e., it will be under biaxial tensile strain. This result is illustrated in FIGS. 2b and 2c. Therefore, a semiconductor device 6 formed on the epitaxial strained silicon layer 10 will have a channel region 20 that is under biaxial tensile strain. In this approach, the relaxed SiGe buffer layer 12 acts as a stressor that introduces strain in the channel region 20. The stressor, in this case, is placed below the channel region 20.

Significant mobility enhancement has been reported for both electrons and holes in bulk transistors using a silicon channel under biaxial tensile strain. In the above mentioned approach, the epitaxial silicon layer is strained before the formation of the transistor. But there are concerns about the strain relaxation upon subsequent CMOS processing where high temperatures are used. In addition, this approach is very expensive since a SiGe buffer layer with thickness in the order of micrometers has to be grown. Numerous dislocations in the relaxed SiGe buffer layer exist and some of these dislocations propagate to the strained silicon layer, resulting in a substrate with high defect density. Thus, this approach has limitations that are related to cost and fundamental material properties.

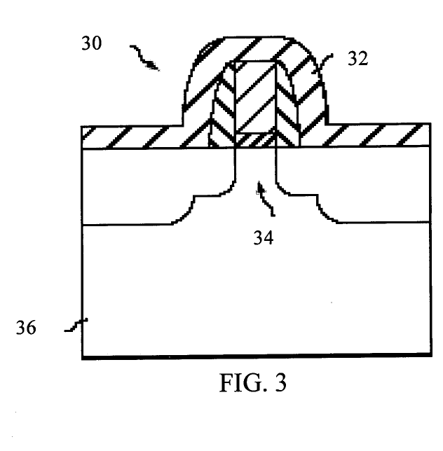

In another preferred method shown in FIG. 3, strain in the channel is introduced after the transistor is formed. In this approach, a high stress film 32 is formed over a completed transistor structure 30 formed in a silicon substrate 36. The high stress film or stressor 32 exerts significant influence on the channel 34, modifying the silicon lattice spacing in the channel region, and thus introducing strain in the channel region. In this case, the stressor 32 is placed above the completed transistor structure. This scheme is described in detail in a paper by A. Shimizu et al., entitled “Local mechanical stress control (LMC): a new technique for CMOS performance enhancement,” published in pp. 433-436 of the Digest of Technical Papers of the 2001 International Electron Device Meeting, which is incorporated herein by reference.

The strain contributed by the high stress film 32 is believed to be uniaxial in nature with a direction parallel to the source-to-drain direction. However, uniaxial tensile strain degrades the hole mobility while uniaxial compressive strain degrades the electron mobility. Ion implantation of germanium may be used to selectively relax the strain so that the hole or electron mobility is not degraded, thereby enabling a high stress film to improve the performance of both PMOS and NMOS devices.

On the other hand, strain is known to be also introduced in the channel region by the formation of the isolation structure, such as the shallow trench isolation structure. In the prior art, the same isolation structure is used for all transistors, whether n-channel or p-channel transistors.

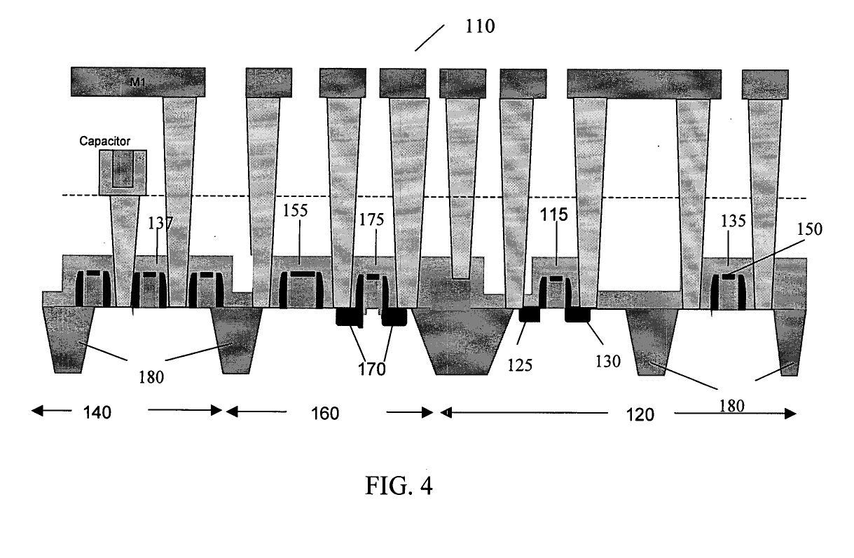

With reference now to FIG. 4, there is shown a cross sectional, side elevation view of an integrated circuit device 110 made in accordance with one or more preferred embodiments of the present invention. In accordance with preferred embodiments of the invention, the performance of transistors may be improved by using different stressors, which may include strain materials and strain methodologies, at different regions of the integrated circuit device. The yield learning and manufacturing cost will be improved. At the same time, device performance should be enhanced as well.

In one example, the present invention may be embodied in a semiconductor device, such as an integrated circuit formed on a substrate. As shown in the FIG. 4, the device 110 includes at least one PMOS device 115 in a logic core region 120, the PMOS device 115 having a first strained material incorporated into its source 125 and drain 130 regions. The device 110 further includes and at least one NMOS device 135 in the logic core region 120 and at least one additional NMOS device 137 in an embedded memory cell 140. An NMOS device may further include a second stressor, such as a tensile film (see e.g. 32 in FIG. 3), in its structure.

In preferred embodiments, the second stressor comprises a contact etch stop layer, preferably greater than about 250 Å thick and preferably exerting a stress greater than about 5.0×10⁴ Dynes/cm. The second stressor preferably comprises silicon nitride that may be formed by low pressure chemical vapor deposition (LPCVD) techniques or plasma enhanced chemical vapor deposition (PECVD) techniques.

Returning to FIG. 4, the first stressor in the source 125 and drain 130 may comprise silicon, germanium, gallium, arsenide, carbon, or other materials having a lattice structure mismatch with the substrate or the region surrounding the stressor. In the case of a SiGe stressor, the composition may preferably include up to about 25% Ge. In another embodiment, the Ge content may be distributed non-uniformly, as in a gradient, in the stressor.

Transistor devices include a gate electrode, the gate electrode preferably less than about 90 nm. An illustrative gate structure 150, as shown in FIG. 4, may have a gate dielectric having a dielectric constant greater than about 3.9, such as silicon oxide, aluminum oxide, silicon oxynitride, silicon nitride, SiO₂, Al₂O₃, SiON, or Si₃N₄, for example, and a gate conductor formed of, e.g., polysilicon, metal, a metal silicide, or combinations of these materials. Silicide materials 150 in the gate, as well as in the source/drain 125, 130 regions may include, for instance, CoSi, NiSi, with a thickness preferably in the range of about 100 to about 400 Angstroms.

In another illustrative embodiment, the integrated circuit 110 described above may include at least one MOS device 175 in an I/O and analog region 160 having a stressor 170 incorporated into its structure and at least one other MOSFET 155 in the same region not having the stressor incorporated into its structure. One skilled in the art recognizes that the strain inducing material 170 may represent SiGe, as in the case of a PMOS device. Similarly, one so skilled would recognize alternative stressors available to a NMOS device, such as a strained etch stop layer, for example.

In yet another illustrative embodiment (not shown), the integrated circuit described above may include at least one. PMOS device in a first region of a logic core region having a first stressor incorporated into its structure and at least one other PMOS device in a second region of the logic core region not having the first stressor incorporated into its structure. The integrated circuit further comprises at least one NMOS device in the logic core and at least one device in an embedded memory cell having the second stressor incorporated into their respective structures.

The substrate of the above described embodiments may comprise bulk silicon substrates, with <100> or with <110> orientation, silicon on insulator (SOI) substrates, or substrates formed of other materials such as SiGe, SiGeC, or quartz, for example. Regions of the substrate are preferably insulated from one another by isolation regions, such as shallow trench isolation, STI, regions. Illustrative examples may include an STI region, 180 of FIG. 4, with a depth greater than about 2500 Angstroms, with an oxide liner about 50 to 300 Angstroms and/or a silicon nitride liner about 50 to about 300 Angstroms.

The above described memory cells may be part of a memory array such as a static random access memory (SRAM), a dynamic random access memory (DRAM), a flash memory, erasable programmable read only memory (EPROM), an electrically erasable programmable read only memory (EEPROM), and the like. While the individual devices have been described above with reference to a transistor, devices such as capacitors, resistors, I/O devices, and the like may also be employed using advantageous features of the invention. Methods for fabricating the first stressors are taught in co-pending application Ser. No. 10/423,513 (TSM03-0173), which is incorporated herein by reference.

Although the present invention and its advantages have been described in detail, it should be understood that various changes, substitutions and alterations may be made herein without departing from the spirit and scope of the invention as defined by the appended claims. For example, it will be readily understood by those skilled in the art that materials and methods may be varied while remaining within the scope of the present invention. For example, the present invention is not limited to silicon based ICs, but it is useful for compound semiconductor devices such as gallium arsenide as well.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a PMOS device in a logic core region of a substrate, wherein the PMOS device comprises a source and a drain, and at least one of the source and drain comprises a first stressor;
a first NMOS device in the logic core region of the substrate, wherein the first NMOS device comprises a second stressor; and
a second NMOS device in an embedded memory cell of the substrate, wherein the second NMOS device comprises the second stressor.

2. The semiconductor device according to claim 1, wherein the substrate comprises a bulk silicon substrate with <100> orientation.

3. The semiconductor device according to claim 1, wherein the substrate comprises a bulk silicon substrate with <110> orientation.

4. The semiconductor device according to claim 1, wherein the substrate is an SOI substrate.

5. The semiconductor device according to claim 1, wherein at least one of the PMOS device, the first NMOS device and the second NMOS device comprises a gate structure having a dimension less than about 90 nm.

6. The semiconductor device according to claim 5, wherein the gate structure comprises polysilicon.

7. The semiconductor device according to claim 5, wherein the gate structure comprises metal.

8. The semiconductor device according to claim 5, wherein the gate structure comprises metal silicide.

9. The semiconductor device according to claim 5, wherein the gate structure comprises a gate dielectric having a dielectric constant greater than about 3.9.

10. The semiconductor device according to claim 1, further comprising a salicide layer in at least one of the source and the drain of the PMOS device.

11. The semiconductor device according to claim 10, wherein the salicide layer comprises CoSi.

12. The semiconductor device according to claim 10, wherein the salicide layer comprises NiSi.

13. The semiconductor device according to claim 10, wherein the salicide layer is about 100 to 400 Å thick.

14. The semiconductor device according to claim 1, wherein the first stressor substantially comprises a SiGe layer.

15. The semiconductor device according to claim 14, wherein the SiGe layer includes less than about 25% Ge.

16. The semiconductor device according to claim 14, wherein the Ge is distributed in a gradient.

17. The semiconductor device according to claim 1, wherein the second stressor comprises a tensile film.

18. The semiconductor device according to claim 1, wherein the second stressor comprises a contact etch stop layer.

19. The semiconductor device according to claim 1, wherein the second stressor comprises a silicon nitride layer.

20. The semiconductor device according to claim 1, wherein the second stressor has a thickness greater than about 250 angstroms.

21. A semiconductor device comprising:
a first PMOS device in a first region of a logic core region of a substrate, wherein the first PMOS device comprises a source and a drain, and at least one of the source and drain of the first PMOS device comprises a first stressor;
a second PMOS device in a second region of the logic core region of the substrate, wherein the second PMOS device comprises a source and a drain, and at least one of the source and drain of the second PMOS device does not comprise the first stressor;
a first NMOS device in the logic core region of the substrate, wherein the first NMOS device comprises a second stressor; and
a second NMOS device in an embedded memory cell of the substrate, wherein the second NMOS device comprises the second stressor.

22. The semiconductor device according to claim 21, wherein the first stressor substantially comprises a SiGe layer.

23. The semiconductor device according to claim 22, wherein the SiGe layer includes less than about 25% Ge.

24. The semiconductor device according to claim 23, wherein the Ge is distributed in a gradient.

25. The semiconductor device according to claim 21, wherein the second stressor comprises a tensile film.

26. The semiconductor device according to claim 21, wherein the second stressor comprises a contact etch stop layer.

27. The semiconductor device according to claim 21, wherein the second stressor comprises a silicon nitride layer.

28. The semiconductor device according to claim 21, wherein the second stressor has a thickness greater than about 250 angstroms.

29. A method of manufacturing a semiconductor structure, the method comprising:
forming a first PMOS device with a source and a drain in a first region of a substrate, wherein at least one the source and drain of the first PMOS device comprises a first stressor;
forming a second PMOS device with a source and a drain in a second region of the substrate, wherein at least one the source and drain of the second PMOS device does not comprise the first stressor;
forming a first NMOS device with a second stressor in the first region of the substrate; and
forming a second NMOS device with the second stressor in a third region of the substrate.

30. The method of claim 29 wherein the first stressor is SiGe.

31. The method of claim 29 wherein the second stressor is silicon nitride.
